(19) United States
(12) Patent Application Publication
(10) Pub. No.: US 2026/0075707 A1
(43) Pub. Date: Mar. 12, 2026

(54) FLEX CIRCUIT CONSTRUCTION FOR BENDING PERFORMANCE

(71) Applicant: Apple Inc., Cupertino, CA (US)

(72) Inventors: Matthew T. Craven, San Jose, CA (US); Babak Ravaji, San Diego, CA (US); Benjamin M. Plattner, Cupertino, CA (US); Christopher P. Glenski, San Francisco, CA (US); Owusu Ansah Agyeman Badu, Santa Clara, CA (US); Phillip Vo, Cupertino, CA (US); Richard D. Shuma, San Jose, CA (US)

(21) Appl. No.: 19/270,780

(22) Filed: Jul. 16, 2025

Related U.S. Application Data
(60) Provisional application No. 63/692,656, filed on Sep. 9, 2024.

(51) Int. Cl. H05K 1/02; H05K 1/18

(52) U.S. Cl. CPC H05K 1/028; H05K 1/0216; H05K 1/189; H05K 2201/055

(57) ABSTRACT

Embodiments include an electronic device that includes an input component movable from an undepressed position to a depressed position, an electronic component, and a flex circuit having a first end coupled to the input component and a second end coupled to the electronic component. The flex circuit can include a first set of layers and a second set of layers. The first set of layers can be coupled to the second set of layers along a first portion of the flex circuit extending from the input component. The first set of layers can be coupled to the second set of layers along a second portion of the flex circuit extending from the electronic component. The first set of layers can be decoupled from the second set of layers along a third portion of the flex circuit extending between the first portion of the flex circuit and the second portion of the flex circuit.

### CROSS REFERENCE TO RELATED APPLICATION

This application is a nonprovisional and claims the benefit under 35 U.S.C. § 119(e) of U.S. Provisional Patent Application No. 63/692,656 filed Sep. 9, 2024, the contents of which are incorporated herein by reference as if fully disclosed herein.

### FIELD

The described embodiments relate generally to circuits for coupling two or more components (e.g., electronic components, input components, or other components) of an electronic device. More particularly, the present embodiments relate to flexible circuits (hereafter “flex circuits”) that may be statically or dynamically bent (with the latter including flex circuits that may be flexed to assume two or more different positions, at least one position of which causes the flex circuit to bend).

### BACKGROUND

Electronic devices and systems may include flex circuits that electrically couple different components. In some cases, the components may move or be moved with respect to each other. For example, a user-operable button may be pressed by a user to provide user input via the button, and the press may cause the button to move with respect to a printed circuit board that receives, transfers, or processes a signal corresponding to the user input. The button and PCB may be electrically coupled by a flex circuit that moves to different positions in response to press and no-press conditions.

Movement between two or more components of an electronic device or system may be user-initiated, machine-initiated, or environment-initiated. Regardless, a flex circuit that couples the components may undergo repeated bending, and sometimes unbending, as the electronic device is used. In some cases, the repeated bending can damage the flex circuit; and in some cases, the flex circuit may fail.

In some cases, two or more components of an electronic device or system may not move with respect to each other, but may be electrically coupled by a flex circuit that is statically bent. Despite the lack of movement of the flex circuit, its bent state may introduce stresses or strains that, over time, damage the flex circuit or cause the flex circuit to fail.

### SUMMARY

Embodiments are directed to an electronic device that includes an input component movable from an undepressed position to a depressed position, an electronic component, and a flex circuit having a first end coupled to the input component and a second end coupled to the electronic component. The flex circuit can include a first set of layers and a second set of layers. The first set of layers can be coupled to the second set of layers along a first portion of the flex circuit extending from the input component. The first set of layers can be coupled to the second set of layers along a second portion of the flex circuit extending from the electronic component. The first set of layers can be decoupled from the second set of layers along a third portion of the flex circuit extending between the first portion of the flex circuit and the second portion of the flex circuit.

Embodiments also include an electronic device that includes a flex circuit. The flex circuit can include a first coupling region positioned at a first end of the flex circuit, where the first coupling region includes first conductive connectors. The flex circuit can include a second coupling region positioned at a second end of the flex circuit, where the second coupling region can include second conductive connectors. The flex circuit can include a first set of layers that extend between the first coupling region and the second coupling region, and a second set of layers that extend between the first coupling region and the second coupling region. The first set of layers can be coupled to the second set of layers along a first portion of the flex circuit extending from the first coupling region. The first set of layers can be coupled to the second set of layers along a second portion of the flex circuit extending from the second coupling region. The first set of layers can be decoupled from the second set of layers along a third portion of the flex circuit extending between the first portion of the flex circuit and the second portion of the flex circuit.

Embodiments further include an electronic device that includes a first electronic component, a second electronic component configured to move with respect to the first electronic component, and a flex circuit extending between the first electronic component and the second electronic component. The flex circuit can be configured to bend in response to the first electronic component moving with respect to the second electronic component. The flex circuit can include a first coupling region including first conductive connectors that electrically couple with the first electronic component, and a second coupling region including second conductive connectors that electrically couple with the second electronic component. The flex circuit can include a first set of layers that extend between the first coupling region and the second coupling region. The flex circuit can include a second set of layers that extend between the first coupling region and the second coupling region. The second set of layers can be coupled to the first set of layers at the first and second coupling regions and decoupled from the first set of layers between along a portion of the flex circuit between the first and second coupling regions.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows an electronic device incorporating a flex circuit according to the present disclosure.

FIG. 2 shows a detailed view of the button structure of the electronic device having a flex circuit as described herein.

FIG. 3 shows an example flex circuit that can be incorporated into an electronic device as described herein.

FIG. 4A shows an example cross-sectional view of the flex circuit of FIG. 3.

FIG. 4B shows an example cross-sectional view of the flex circuit of FIG. 3.

FIGS. 5A and 5B show an example bending of a flex circuit in response to movement of an electronic component.

FIG. 6A-6C show example stack-ups of flex circuits that include multiple sets of layers.

FIG. 7 shows an example block diagram of an electronic device as described herein.

It should be understood that the proportions and dimensions (either relative or absolute) of the various features and elements (and collections and groupings thereof) and the boundaries, separations, and positional relationships presented there between, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

Embodiments disclosed herein are directed to electronic devices that include a flex circuit that couples two or more electronic components and is subjected to repeated bending (or other deformation) during use of the electronic device. The flex circuit can have multiple layers including one or more signal layers, one or more cover layers, and one or more shielding layers. The signal layer(s) include conductive traces, that include a metal or other conductive material and are used to electrically couple different electronic components. The shielding layer(s) also include a metal or other conductive material, which may function as an electromagnetic interference shield, a ground reference, and/or impedance matching layer for the signal layer. As the electronic device is used, movement between electronic components can cause the flex circuit to bend (or otherwise deform) or unbend, and the repeated bending and/or unbending can stress the signal layer and/or the shielding layer causing the metal material to crack or otherwise be damaged thereby inhibit functioning of these layers. Moreover, the multiple layer stack-up of the flex circuits can cause the signal layer(s) and/or the shielding layer(s) to be positioned further from the neutral bending axis of the flex circuit stack up, which can cause increase stress in the metal components of the layers.

The examples provided herein discuss the flex circuit in the context of bending from a first state to a second state in response to movement of one or more electronic components. The bending, as provided herein can also include unbending, in which a flex circuit moves from the second state to the first state. Additionally or alternatively, bending can include movement/deformation of the flex circuit from an unbent state to a bent state, from a first bent state to a second bent state or combinations thereof.

The examples provided herein discuss the flex circuit in the context of coupling various electronic component. Generally and broadly, the flex circuits described here can also be used to couple various structural components which may or may not include electronic elements. For example, in some cases, the flex circuit can include optical elements that transmit optical signals between various components. The optical circuits may be separate from or integrated with electronic components.

The flex circuits described herein include a design that reduces bending stress along at least a portion of a flex circuit stack up by decoupling a portion of different sets of layers from each other. This decoupling shifts the neutral bending axis closer to the signal layer and/or shielding layer, thereby reducing bending stress in these layers. The flex circuits have a design in which the different layers of the flex circuits are coupled along end portions of the flex circuits. Along central portions of the flex circuits (or at least portions between the end portions), the sets of layers are decoupled from each other. The decoupling of the sets of layers can allow these layers to move/bend independent of each other, thereby changing the neutral bending axis from a central portion of the entire stack to the individual decoupled sets of layers.

In some cases, an example of the flex circuit can include coupling regions at each end of the flex circuit. The coupling regions can be configured to mechanically and electrically couple each end of the flex circuit to an electronic component of the electronic device. For example, the coupling regions can include conductive connectors that electrically couple the flex circuit to a corresponding electronic component. The flex circuit can include multiple layers that extend between the coupling regions and include conductive traces that transfer signals between the coupling regions and corresponding electronic components. The multiple layers can include a first set of layers that include conductive traces for transferring electrical signals. The first set of layers can include a base layer, conductive traces on the base layer and a cover layer that surrounds and electrically insulates the conductive traces. The multiple layers can include a second set of layers that includes one or more shielding components for shielding the conductive traces from EMI, function as a ground reference or an impedance matching layer, and/or so on. The second set of layers can include a conductive material on a base layer and a cover layer that surrounds the conductive material.

The first set of layers can be coupled to the second set of layer along a first portion of the flex circuit extending from the first coupling region. The first set of layers can also be coupled to the second set of layers along a second portion of the flex circuit extending from the second coupling region. The first set of layers can be decoupled from the second set of layers along a third portion of the flex circuit, which is located between the first and second portions.

The decoupled sets of layers along the third portion can move with respect to each other. In some cases there may be an air gap between the first set of layers and the second set of layers.

Accordingly, in the first and second portions of the flex circuit the neutral bending axis is positioned within the entire stack of the multiple layers (e.g., located centrally within the stack) and each of the first set of layers and the second set of layer may be offset from the neutral bending axis. In the third, decoupled portion, the first set of layers includes a first neutral bending axis that is located within these first layers, and the second set of layers includes a second neutral bending axis that is located within these second layers. Accordingly, when the device undergoes bending (or other deformation) the stress in each of the first and second sets of layers is reduced in the third portion of the flex circuit.

The flex circuit can be designed and integrated with the electronic device such that the third portion of the flex circuit is located along portions of the flex circuit that undergo greater amounts of bending/deformation when the device is being used.

Additionally, flex circuit may include additional sets of layers in the multi-layered stack. These additional sets of layers can include signal layers or shielding layers and be coupled to other sets of layers along the first and second portions of the flex circuit and decoupled from other layers along the third portion of the flex circuit, as described herein. In some cases, the flex circuit can include one or more vias that electrically couple different layers of the flex circuit. For example, the vias may couple a shielding layer to ground elements within a signal layer. The vias can be positioned along the first and second portions of the flex circuit where the sets of layers are coupled together.

In some cases, the flex circuit may have a bent/arcuate configuration when integrated with the electronic device, and may bend, flex, or otherwise deform from the bent configuration. In these cases, the different sets of layers can have different lengths along the third portion of the flex circuit to reduce stress when the flex circuit is integrated into the bent configuration within the device. For example, the set of layers that is further from an axis of bending can have a greater length to account for the greater arc length of these layers when the flex circuit is in the bent configuration.

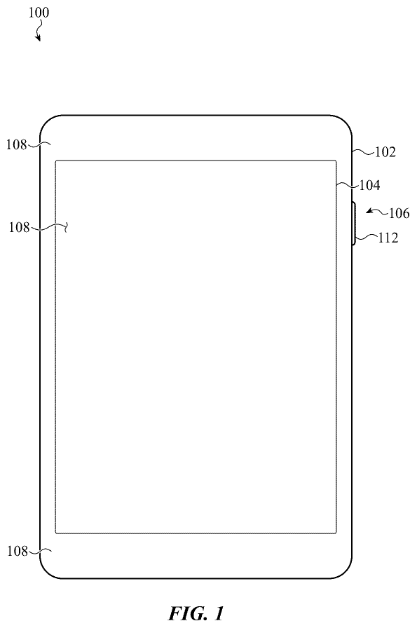

These and other embodiments are discussed below with reference to FIG. 1-7. However, those skilled in the art will readily appreciate that the detailed description given herein with respect to these figures is for explanatory purposes only and should not be construed as limiting.

FIG. 1 shows an electronic device which can include a flex circuit, as described according to the present disclosure. In the illustrated embodiment, the electronic device 100 is implemented as a tablet computing device. Other embodiments can implement the electronic device differently. For example, an electronic device can be a smart phone, a laptop computer, a wearable computing device, a digital media player, a kiosk, a stand-alone touch screen display, a mouse, a keyboard, and other types of electronic devices that include flex circuits that couple electronic components.

The electronic device 100 includes a housing 102 at least partially surrounding a display 104. The housing 102 can enclose, or partially enclose, the display and other internal components of the electronic device 100. The housing 102 can be formed of one or more components operably connected together, such as a front piece and a back piece. Alternatively, the housing 102 can be formed of a single piece operably connected to the display 104.

The display 104 can provide a visual output to the user. The display 104 can be implemented with any suitable technology, including, but not limited to, a liquid crystal display element, a light-emitting diode element, an organic light-emitting diode element, an organic electroluminescence element, and the like.

A cover sheet 108 may be positioned over the front surface (or a portion of the front surface) of the electronic device 100. In some embodiments, at least a portion of the cover sheet 108 can sense touch and/or force inputs. The cover sheet 108 can be formed with any suitable material, such as glass, plastic, sapphire, or combinations thereof. In some embodiments, touch and force inputs can be received by the portion of the cover sheet 108 that covers the display 104. In some embodiments, touch and/or force inputs can be received across other portions of the cover sheet 108 and/or portions of the housing 102.

Various layers of a display stack (such as the cover sheet 108, display 104, touch sensor layer, force sensor layer, and so on) may be adhered together with an adhesive and/or may be supported by a common frame or portion of the housing 102. A common frame may extend around a perimeter, or a portion of the perimeter, of the layers, may be segmented around the perimeter or a portion of the perimeter, or may be coupled to the various layers of the display stack in another manner.

In some embodiments, each of the layers of the display stack may be attached or deposited onto separate substrates that may be laminated or bonded to each other. The display stack may also include other layers for improving the structural or optical performance of the display 104, including, for example, polarizer sheets, color masks, and the like. Additionally, the display stack may include a touch and/or force sensor layer for receiving inputs on the cover sheet 108 of the electronic device 100. FIG. 1 is described with respect to an electronic device incorporating a display 104 and a cover sheet 108; other embodiments may omit the display 104 and/or the cover sheet 108.

In many cases, the electronic device 100 can also include a processor, memory, power supply and/or battery, network connections, sensors, input/output ports, acoustic components, haptic components, digital and/or analog circuits for performing and/or coordinating tasks of the electronic device 100, and so on. For simplicity of illustration, the electronic device 100 is depicted in FIG. 1 without many of these components, each of which may be included, partially and/or entirely, within the housing 102. Examples of such components are described below with respect to FIG. 8.

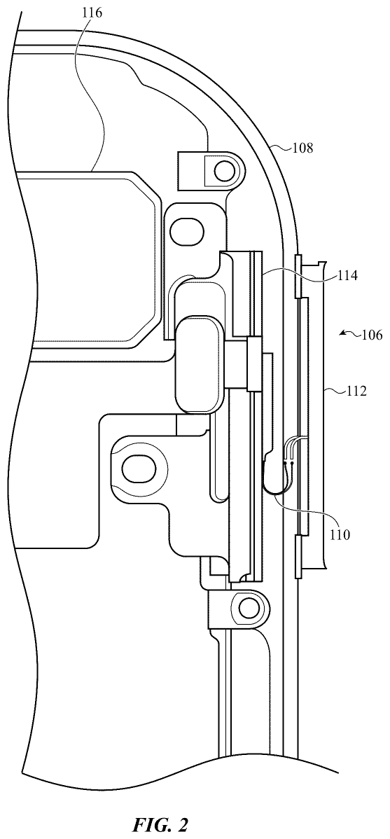

The electronic device 100 can include an input assembly 106, an example of which is shown as a button assembly. The input assembly 106 can include an input component (e.g., a button) 112 that moves with respect to the housing 102. For example, the input component 112 can move a from an undepressed position to a depressed position in response to a force input received from a user. The electronic device 100 can include a flex circuit 110 (shown in FIG. 2) which electrically couples the input component 112 to other electronic component(s) and bends or otherwise deforms in response to the input component 112 moving.

FIG. 2 shows a detailed view of the input assembly 106 of the electronic device having a flex circuit 110 as described herein. The input assembly 106 can include an input component 112 and an input assembly mounting tab 114. The input component 112 can be configured to move with respect to the mounting tab 114, which can be fixed to the housing 102. In some cases, the flex circuit 110 can extend between the input component 112 and the mounting tab 114. The flex circuit 110 can electrically couple the input component 112 to the electronic component 116 (e.g., a PCB or circuit module). For example, the input component 112 may include one or more electronic assemblies such as a touch sensor, fingerprint reader, force sensor, and so on. The flex circuit 110 can be configured to transfer electrical signals between these electronic assemblies and other electronic components, such as electronic component 116, which may include a processor or other component used to process electrical signals receive from or sent to the input component 112.

A first portion of the flex circuit 110 can be coupled to the input component and a second portion of the flex circuit 110 can be coupled to the electronic component 116. As the input component 112 moves from an undepressed position to a depressed position and/or from the depressed position to the undepressed position, the movement of the input component 112 can cause the flex circuit 110 to bend.

The integration of the flex circuit 110 into the input assembly 106 is provided as an example and the flex circuit 110 can alternatively be integrated into other assemblies and/or other types of devices. For example, the flex circuit 110 can be integrated into devices such as a laptop, in which an upper portion including a display moves with respect to a lower portion. In these cases, the flex circuit 110 can couple components in the upper portion to components in the lower portion. The flex circuit 110 can also be integrated into other devices, in which one or more components move with respect to each other (e.g., in smartwatches, smartphones, tablets, head-worn devices, other wearable devices, and/or other types of electronic devices).

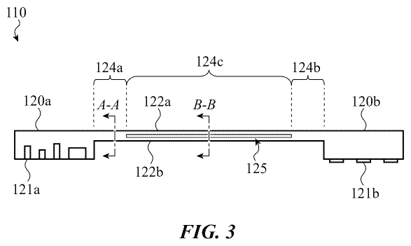

FIG. 3 shows an example of the flex circuit 110, as described herein. The flex circuit 110 can include a first coupling region 120a, a second coupling region 120b and multiple layers 122 that extend between the first coupling region 120a and the second coupling region 120b.

The first coupling region 120a and the second coupling region 120b can each electrically and mechanically couple the flex circuit 110 to a respective electronic component. For example, the first coupling region 120a can couple a first portion of the flex circuit 110 (e.g., a first end of the flex circuit 110) to the input component 112, and the second coupling region 120b can couple a second portion of the flex circuit 110 (e.g., a second end to of the flex circuit 110) to the electronic component 116. The first coupling region 120a can include one or more first conductive connectors 121a (one of which is labeled) and the second coupling region 120b can include one or more second conductive connectors 121b (one of which is labeled). The conductive connectors can include metal or other conductive materials that electrically and/or mechanically couple to connectors on a respective electronic component. For example, the conductive connectors can be provided in a connector module that is electrically coupled to the flex circuit, provided as conductive pads that are formed on or in the flex circuit or configured in other ways.

The multiple layers 122 can include a first set of layers 122a and a second set of layers 122b. In some cases, the first set of layers 122a may be stacked with the second set of layers 122b. The multiple layers 122 can include a first portion 124a and a second portion 124b, in which the first set of layers 122a is coupled to the second set of layers 122b. In some cases, the first and second sets of layers 122a, 122b may be continuous with each other along the first portion 124a and the second portion 124b. The multiple layers 122 can include a third portion 124c, in which the first set of layers 122a is decoupled from the second set of layers 122b. In some cases, the third portion 124c can be located between the first portion 124a and the second portion 124b. Along, the decoupled third portion 124c, the first set of layers 122a can be separate and configured to independently bend (or otherwise move, flex or deform) with respect to the second set of layers 122b. Accordingly, as the flex circuit is bent (or otherwise deformed) the first set of layers 122a and the second set of layers 122b may move with respect to each other along the third portion.

The multiple layers 122 can include one or more conductive traces that electrically couple the first conductive connectors 121a to the second conductive connectors 121a. The multiple layers 122 can also include one or more conductive materials that operate as an electromagnetic shielding layer, ground reference layer, impedance matching layer, and/or the like, as described herein. In some cases, the conductive traces and/or conductive materials can include metals or any other suitable conductive material.

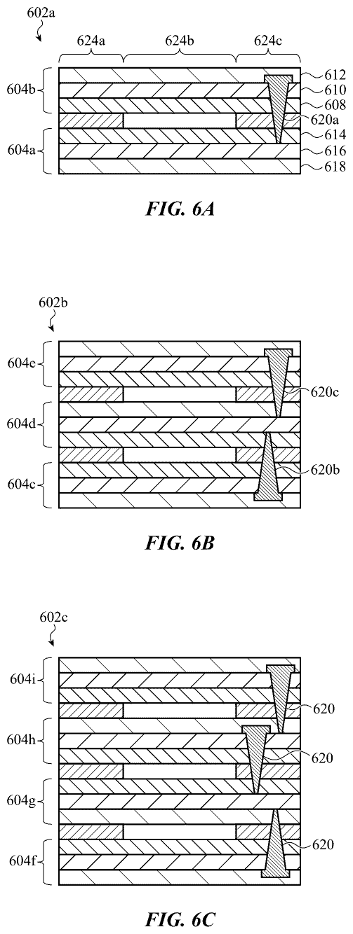

In some cases, multiple layers 122 of the flex circuit 110 can include additional sets of layers. For example, the multiple layers 122 can include a third set of layers that is coupled to the first set of layers 122a and the second set of layers 122b along the first portion 124a and the second portion 124b, and decoupled from the first set of layers 122a and the second set of layers 122b along the third portion 124c. Examples of devices including additional sets of layers are further described herein, including with respect to FIGS. 6B and 6C.

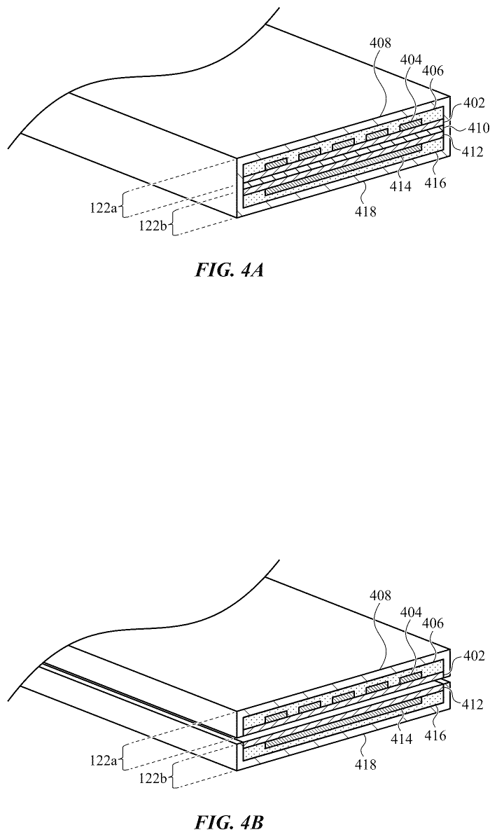

FIG. 4A shows a cross-sectional view of the flex circuit 110 taken along line A-A shown in FIG. 3, which corresponds to a location where the first set of layers 122a is coupled to the second set of layers 122b. The first set of layers 122a can include a base layer 402, one or more conductive traces 404, a coupling material 406 (which may also be referred to herein as an adhesive material), and a cover layer 408. The second set of layers 122b can include a base layer 412, one or more conductive traces 414, a coupling material 416, and a cover layer 418. The first set of layers 122a can be coupled to the second set of layers 122b by an adhesive layer 410.

The one or more conductive traces 404 can be used to transmit electrical signals between a first electronic component (e.g., the input component 112) and a second electronic component (e.g., a PCB on which a processor or other circuit components are mounted). The first set of layers 122a can include multiple conductive traces that are electrically isolated from each other and can independently carry electrical signals. The conductive traces 404 can be formed from any suitable material including metals (e.g., copper, nickels, alloys, or any other suitable metal), graphene, conductive polymers, and so on. Various one of the conductive traces 404 can have different sizes, materials or other configurations and may be configured for carrying specific types of electrical signals. For example, one or more of the conductive traces 404 may be configured to supply power to a device, and other traces may be configured to carry data signals such as digital or analog signals. Accordingly, the power traces may have a different size (e.g., larger size) and/or include different conductive materials as compared to traces that are configured to carry data signals.

The one or more conductive traces 404 can be coupled to the base layer 402 and an adhesive material 406 can cover the conductive traces 404 and/or portions of the base layer 402. The adhesive material 406 can couple the base layer 402 and the conductive traces 404 to the cover layer 408. The base layer 402, the conductive traces 404, the adhesive material 406 and the cover layer 408 can form a flexible set of layers that can bend (or otherwise deform), as described herein. The base layer 402 and/or the cover layer 408 can be formed from any suitable materials, including, for example, polymer materials (e.g., polyimide). The base layer 402, the adhesive material 406 and/or the cover layer 408 can include materials that electrically insulate the conductive traces 404.

In some cases, one or more conductive traces 414 can be configured as an EMI shielding layer. Additionally or alternatively, the conductive traces 414 can be configured to function as a ground reference(s) and/or provide impedance matching for electrical signals transferred using the flex circuit 110. In other cases, the one or more conductive traces 414 can carry electrical signals, in addition to or as an alternative to, the conductive traces 404. In some cases, the flex circuit 110 can include a conductive material that extends across a width of the multiple layers 122. For example, a single conductive trace 414 on one layer may extend across multiple conductive traces of the conductive trace(s) 404 on another layer. In these examples, the conductive material may operate as an EMI shield to external sources of interference. The one or more conductive traces 414 can include a pattern that reduces bending stress in the material forming the trace(s) 414. For example, the conductive trace 414 can include a cross-hatch pattern or one or more openings formed in the conductive material. For example, the cross-hatch pattern or openings may be areas where material is removed and/or include areas that have thinner portions of the conductive material, thereby reducing a bending stress in the conductive tracs 414.

The one or more conductive traces 414 can be coupled to the base layer 412, and an adhesive material 416 can cover the conductive traces 414 and/or portions of the base layer 412. The adhesive material 416 can couple the base layer 412 and the conductive traces to the cover layer 418. The base layer 412, the conductive traces 414, the adhesive material 416 and the cover layer 418 can form a flexible set of layer that can bend (or otherwise deform), as described herein. The base layer 412 and/or the cover layer 418 can be formed from any suitable materials, including, for example, polymer materials (e.g., polyimide). The base layer 412, the adhesive material 416 and/or the cover layer 418 can include materials that electrically insulate the conductive traces 414.

The adhesive layer 410 can constrain movement of the first set of layers 122a with respect to the second set of layers 122b. The adhesive layer 410 can include any suitable adhesive that couples the first set of layers 122a to the second set of layers 122b, including curable liquid adhesives, pressure sensitive adhesives and so on.

A length of the first portion 124a (and/or of the second portion 124b) of the multiple layers 122 can be defined by the portion of the first set of layers and the second set of layers coupled together (e.g., by the adhesive layer 410). In some cases, the first portion 124a and the second portion 124b can have a higher stiffness due to the first set of layers 122a being coupled to the second set of layers 122b. The first portion 124a and the second portion can create regions of the multiple layers, extending from the coupling regions 120, that are reinforced as compared to the layers in the third portion 124c. The reinforced first portion 124a and second portion 124b, combined with the reduced bending stress of the third portion 124c, can help increase a fatigue level or reduce breakdown of the flex circuit (e.g., reduce failure or degradation of the conductive materials).

FIG. 4B shows a cross-sectional view of the flex circuit 110 taken along line B-B shown in FIG. 3, which corresponds to a location where the first set of layers 122a is decoupled from the second set of layers 122b (e.g., the third portion 124c). The first set of layers 122a can include a base layer 402, one or more conductive traces 404, a coupling material 406, and a cover layer 408. The second set of layers 122b can include a base layer 412, one or more conductive traces 414, a coupling material 416, and a cover layer 418. The first set of layers 122a can be separated from/not coupled to the second set of layers 122b. Accordingly, in the third portion 124c, the first set of layers 122a can move with respect to the second set of layers 122b to a greater extent than in the first portion 124a or the second portion 124b. In some cases, the first set of layers 122a may be separated from the second set of layers 122b by a gap 411 (e.g., an air gap).

Along the third portion 124c, the base layer 402 and/or cover layer 408 can surround the conductive traces 404 (and/or other layers of the first set of layers 122a) and the base layer 412 and/or the cover layers 418 can surround the conductive traces 414 (and/or other layers of the second set of layers 122b).

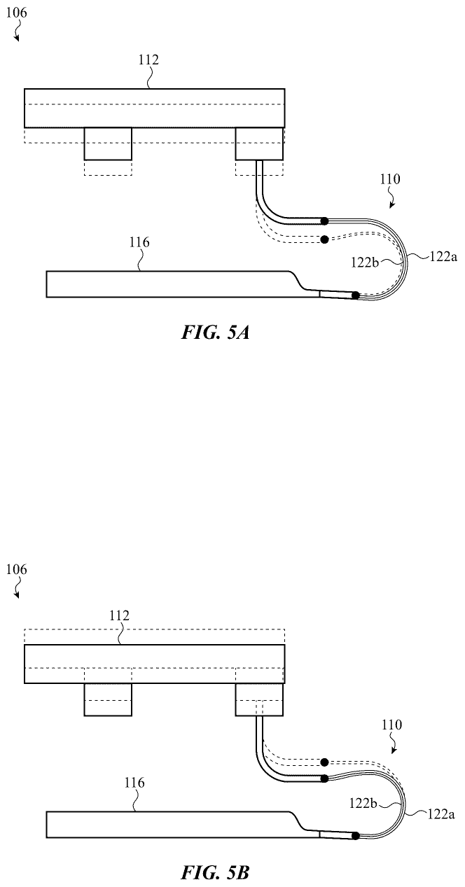

FIGS. 5A and 5B show an example bending of the flex circuit 110 in response to movement of an electronic component. FIG. 5A shows a simplified example of the input assembly 106 in an undepressed condition and FIG. 5B shows a simplified example of the input assembly 106 in the depressed condition. The flex circuit 110 can define an arcuate profile between a first electronic component (e.g., the input component 112) and a second electronic component (e.g., electronic component 116). In the illustrated example, the flex circuit defines a bend radius along the third portion 124c. As the input component moves between the undepressed and the depressed portions, the flex circuit 110 primarily bends along the third portion 124c, where the first set of layers 122a is decoupled from the second set of layers 122b.

The decoupling of the first set of layers 122a from the second set of layers 122b can change the neutral bending axis along the third portion 124c as compared to the first portion 124a and the second portion 124b of the flex circuit 110. For example, the first portion 124a and the second portion 124b can include a neutral bending axis that is defined by the combination of both the first set of layers 122a and the second set of layers 122b, since these sets of layers are coupled to each other along these portions. Accordingly, the conductive traces 304 and 314 may be offset from the neutral bending axis along the first portion 124a and the second portion 124b. Along the third portion, the decoupling of the first set of layers 122a from the second set of layers 122b can create a first neutral bending axis that is located closer to the conductive traces 304 with the first set of layers, and a second neutral bending axis that is closer to the conductive traces 314 in the second set of layers. Accordingly, bending stress may be reduced in the third portion 124c of the flex circuit 110 as compared to the first portion 124a and the second portion 124b.

In some cases, a length of the first set of layers 122a along the third portion 124c can be different from a length of the second set of layers 122b to account for differences in arc length due to the arcuate profile of the flex circuit. For example, the first set of layers 122a may have a longer arc length due to being positioned further from a bend axis as compared to the second set of layers 122b. Accordingly, the first set of layers 122a can be longer than the second set of layers 122b along the third portion 124c. In some cases, the difference in length between the first set of layers 122a and the second set of layers is based at least in part on the bend radius.

Additionally or alternatively, the first portion 124a and/or the second portion 124b of the flex circuit 110 can include reinforcement. For example, one or more of the first set of layers 122a or the second set of layers 122b can include stiffeners (e.g., stiffer and/or thicker layers or additional layers), which may further reduce bending along these portions as compared to the third portion 124c of the flex circuit 110. In some cases, the reinforcement can include external clamps or similar reinforcement that surround the first set of layers 122a and/or the second set of layers 122b along the first portion 124a and/or the second portion 124b. In some cases, the flex circuit 110 can include reinforcement (e.g., stiffener, clamp, and so on) at a transition between the first portion 124a and the third portion 124c and/or between the second portion 124b and the third portion 124c.

FIG. 6A-6C show example cross-sectional views of stack-ups of flex circuits 602. FIG. 6A shows an example flex circuit 602a having two sets of layers. FIG. 6B shows an example of flex circuit 602b having 3 sets of layers. FIG. 6C shows an example flex circuit 602c having four sets of layers. The flex circuit 602 can include vias 620 that electrically couple different layers of the flex circuits 602 (e.g., to route electrical signals and/or grounds between different layers).

The flex circuit 602a can include a first set of layers 604a and a second set of layers 604b, which may be an example of the flex circuits described herein. For example, the first set of layers may correspond to the first set of layers 122a, and the second set of layers 604b may correspond to the second set of layers 122b, as described herein. The flex circuit 602a can include a first portion 606a, which may correspond to first portion 124a; a second portion 606b, which may correspond to second portion 124b; and a third portion 606c, which may correspond to the third portion 124c, as described herein. For example, the first set of layers 604a can be coupled to the second set of layers 604b along the first portion 606a and the second portion 606b, and the first set of layers 604a can be decoupled from the second set of layers 604b along the third portion 606c.

The first set of layers 604a can include a base layer 608, one or more first conductive traces 610, and a cover layer 612, as described herein. The second set of layers 604b can include a base layer 614, one or more second conductive traces 616, and a cover layer 618, as described herein. In some cases, a via 620a can electrically couple one or more of the first conductive traces 610 to the one or more second conductive traces. The via 620a can be positioned along the second portion 606b (as shown in FIG. 6A) and/or along the first portion 606a where the first set of layers 604a are coupled to the second set of layers 604b.

In some cases, the flex circuit 602a can include multiple vias 620a (one of which is shown). For example, different vias 620a may be used to coupled different conductive traces between the first set of layers 604a and the second set of layers 604b.

The flex circuit 602b, shown in FIG. 6B, shows an example of a three-set stack up. The flex circuit 602b can include a first set of layers 604c, a second set of layers 604d and a third set of layers 604e. The first, second and third sets of layers can be coupled along first and second portions and decoupled along a third portion, as described herein. In some cases, the flex circuit can include multiple vias that connect conductive traces of different layers. For example, the flex circuit 602b can include a first via 620b that eclectically couples one or more conductive traces of the first set of layers 604c with one or more traces of the second set of layers 604d. Additionally or alternatively, the flex circuit 602b can include a second via 620c that electrically couples one or more conductive traces of the third set of layers 604e with one or more traces of the second set of layers 604d. In some cases, the flex circuit 602b can include vias that couple conductive traces of the first set of layers 604c with conductive traces of the third set of layers 604e.

In some cases, the different sets of layers can have different functionality. For example, the first set of layers 604c and the third set of layers 604e may function as EMI shielding layers on each side of the second set of layers 604d. In other cases, the flex circuit 602b may have multiple set of layers that carry data signals. For example, the first set of layers 604c may include conductive traces and be operable to carry first electrical signals (e.g., analog or digital signals), the second set of layers 604d may include conductive traces that carry additional electrical signals, which may be the similar or different from the first electrical signals (e.g., configured as higher speed data transfer traces) and the third set of layers 604e may function as shielding layers, ground reference(s), used for impedance matching, and so on.

The flex circuit 602c, shown in FIG. 6C, shows an example of a four-set stack up. The flex circuit 602c can include a first set of layers 604f, a second set of layers 604g, a third set of layers 604h and a fourth set of layers 604i. The first, second third and fourth sets of layers can be coupled along first and second portions and decoupled along a third portion, as described herein. In some cases, the flex circuit 602c can include multiple vias 620 that connect conductive traces of different layers, as described herein.

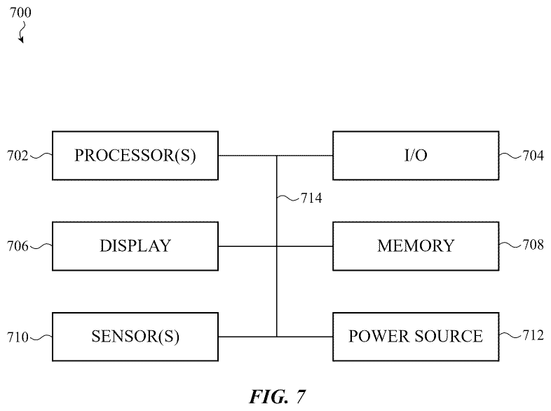

FIG. 7 is an example block diagram of an electronic device 700, which can take the form of any of the devices as described with references to FIG. 1-6. The electronic device 700 can include a processor(s) 702, an input/output (I/O) mechanism 704 (e.g., wired or wireless communications interfaces), a display 706, memory 708, sensor(s) 710 (e.g., physiological sensors such as those described herein), and a power source 712 (e.g., a rechargeable battery). The processor(s) 702 can control some or all of the operations of the electronic device 700. The processor(s) 702 can communicate, either directly or indirectly, with some or all of the components of the electronic device 700. For example, a system bus or other communication mechanism 714 can provide communication between the processor(s) 702, the I/O mechanism 704, the memory 708, the sensor(s) 710, and the power source 712.

The processor(s) 702 can be implemented as any electronic device capable of processing, receiving, or transmitting data or instructions. For example, the processor(s) 702 can be a microprocessor, a central processing unit (CPU), an application-specific integrated circuit (ASIC), a digital signal processor (DSP), or combinations of such devices. As described herein, the term “processor” is meant to encompass a single processor or processing unit, multiple processors, multiple processing units, or other suitable computing element or elements. The processing unit can be programmed to perform the various aspects of the systems described herein.

It should be noted that the components of the electronic device 700 can be controlled by multiple processors. For example, select components of the electronic device 700 (e.g., a sensor 710) may be controlled by a first processor and other components of the electronic device 700 (e.g., the I/O 704) may be controlled by a second processor, where the first and second processors may or may not be in communication with each other.

The I/O device 704 can transmit and/or receive data from a user or another electronic device. An I/O device can transmit electrical signals via a communications network, such as a wireless and/or wired network connection. Examples of wireless and wired network connections include, but are not limited to, cellular, Wi-Fi, Bluetooth, IR, and Ethernet connections. In some cases, the I/O device 704 can communicate with an external electronic device, such as a smartphone, electronic device, or other portable electronic device, as described here.

The sensing system may optionally include a display 706 such as a liquid crystal display (LCD), an organic light-emitting diode (OLED) display, a light-emitting diode (LED) display, or the like. If the display 706 is an LCD, the display 706 may also include a backlight component that can be controlled to provide variable levels of display brightness. If the display 706 is an OLED or LED type display, the brightness of the display 706 may be controlled by modifying the electrical signals that are provided to display elements. The display 706 may correspond to any of the displays shown or described herein.

The memory 708 can store electronic data that can be used by the electronic device 700. For example, the memory 708 can store electrical data or content such as, for example, audio and video files, documents and applications, device settings and user preferences, timing signals, control signals, and data structures or databases. The memory 708 can be configured as any type of memory. By way of example only, the memory 708 can be implemented as random access memory, read-only memory, Flash memory, removable memory, other types of storage elements, or combinations of such devices.

The electronic device 700 may also include one or more sensor(s) 710 positioned almost anywhere on the electronic device 700. The sensor(s) 710 can be configured to sense one or more types of parameters, such as but not limited to, pressure, light, touch, heat, movement, relative motion, biometric data (e.g., biological parameters), and so on. For example, the sensor(s) 710 may include a heat sensor, a position sensor, a light or optical sensor, an accelerometer, a pressure transducer, a gyroscope, a magnetometer, a health monitoring sensor, and so on. Additionally, the one or more sensor(s) 710 can utilize any suitable sensing technology, including, but not limited to, capacitive, ultrasonic, resistive, optical, ultrasound, piezoelectric, and thermal sensing technology.

The power source 712 can be implemented with any device capable of providing energy to the electronic device 700. For example, the power source 712 may be one or more batteries or rechargeable batteries. Additionally or alternatively, the power source 712 can be a power connector or power cord that connects the electronic device 700 to another power source, such as a wall outlet.

The flex circuit described herein can couple two or more components of the electronic device 700. For example, the flex circuit may be coupled to the processor 702 and display and transmit electrical signals between these components. Additionally or alternatively, the flex circuit described herein can couple other components of the electronic device 700, as described herein.

The foregoing description, for purposes of explanation, uses specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device comprising:
an input component, movable between an undepressed position and a depressed position;
an electronic component; and
a flex circuit having a first end coupled to the input component and a second end coupled to the electronic component, the flex circuit comprising a first set of layers and a second set of layers, wherein:
the first set of layers is coupled to the second set of layers along a first portion of the flex circuit extending from the input component;
the first set of layers is coupled to the second set of layers along a second portion of the flex circuit extending from the electronic component; and
the first set of layers is decoupled from the second set of layers along a third portion of the flex circuit extending between the first portion of the flex circuit and the second portion of the flex circuit.

2. The electronic device of claim 1, wherein:
the first set of layers comprises conductive traces electrically coupling the input component to the electronic component; and
the second set of layers comprise a conductive material that extends across the first portion, the second portion and the third portion of the flex circuit.

3. The electronic device of claim 2, wherein
the flex circuit comprises:
a first coupling region positioned at the first end of the flex circuit, the first coupling region comprising first conductive connectors that electrically couple to the input component; and
a second coupling region positioned at the second end of the flex circuit, the second coupling region comprising second conductive connectors that electrically couple to the electronic component; and
the conductive traces couple to the first conductive connectors and the second conductive connectors.

4. The electronic device of claim 2, wherein the conductive material comprises a pattern that alleviates stress in the conductive material when the flex circuit is bent.

5. The electronic device of claim 4, wherein the pattern comprises at least one of a cross-hatch pattern or one or more openings in the conductive material.

6. The electronic device of claim 2, wherein:
the first set of layers comprises a first insulating layer covering the conductive traces; and
the second set of layers comprises a second insulating layer covering the conductive material.

7. The electronic device of claim 2, wherein the flex circuit comprises a via positioned along the first portion of the flex circuit or the second portion of the flex circuit, the via electrically coupling at least one trace of the conductive traces to the conductive material.

8. The electronic device of claim 1, wherein:
the flex circuit defines an arcuate profile having a bend radius;
the first set of layers comprise a first length;
the second set of layers comprise a second length, different from the first length; and
the difference in length between the first set of layers and the second set of layers is based at least in part on the bend radius.

9. The electronic device of claim 1, wherein:
the flex circuit comprises a third set of layers;
the third set of layers is coupled to the first and second sets of layers along the first portion of the flex circuit;
the third set of layers is coupled to the first and second sets of layers along the second portion of the flex circuit; and
the third set of layers is decoupled from the first and second sets of layers along the third portion of the flex circuit.

10. An electronic device comprising:
an input component operable to move between an undepressed position to a depressed position;
an electronic component; and
a flex circuit comprising:
a first coupling region positioned at a first end of the flex circuit, the first coupling region comprising at least one first conductive connector that electrically couples with the input component;
a second coupling region positioned at a second end of the flex circuit, the second coupling region comprising at least one second conductive connector that electrically couples with the electronic component;
a first set of layers that extend between the first coupling region and the second coupling region; and
a second set of layers that extend between the first coupling region and the second coupling region; wherein:
the first set of layers is coupled to the second set of layers along a first portion of the flex circuit extending from the first coupling region;
the first set of layers is coupled to the second set of layers along a second portion of the flex circuit extending from the second coupling region; and
the first set of layers is decoupled from the second set of layers along a third portion of the flex circuit extending between the first portion of the flex circuit and the second portion of the flex circuit.

11. The electronic device of claim 10, wherein:
the first set of layers comprises at least one conductive trace electrically coupling the at least one first conductive connector to the at least one second conductive connector; and
the second set of layers comprises at least one conductive material that is configured to function as an interference shield for electrical signals transmitted using the at least one conductive trace.

12. The electronic device of claim 11, wherein:
the first set of layers comprises a first base layer;
the at least one conductive trace is coupled to the first base layer;
the second set of layers comprises a second base layer; and
the at least one conductive material is coupled to the second base layer.

13. The electronic device of claim 12, wherein:
the first base layer is coupled to the second base layer along the first portion and the second portion of the flex circuit; and
the first base layer is separated from the second base layer by an air gap along the third portion of the flex circuit.

14. The electronic device of claim 10, wherein:
the first set of layers has a first length; and
the second set of layers has a second length, different from the first length.

15. The electronic device of claim 14, wherein:
the flex circuit comprises a bent configuration having a bend radius; and
the difference in length between the first set of layers and the second set of layers is configured to reduce stress in the first set of layers and the second set of layers when the flex circuit is in the bent configuration.

16. The electronic device of claim 10, wherein the flex circuit comprises a via positioned along the first portion of the flex circuit or the second portion of the flex circuit, the via electrically coupling the first set of layers to the second set of layers.

17. An electronic device comprising:
a first electronic component;
a second electronic component configured to move with respect to the first electronic component; and
a flex circuit extending between the first electronic component and the second electronic component, configured to bend in response to the first electronic component moving with respect to the second electronic component and comprise:
a first coupling region coupled to the first electronic component;
a second coupling region coupled to the second electronic component;
a first set of layers that extend between the first coupling region and the second coupling region; and
a second set of layers that extend between the first coupling region and the second coupling region, the second set of layers coupled to the first set of layers at the first and second coupling regions and decoupled from the first set of layers between along a portion of the flex circuit between the first and second coupling regions.

18. The electronic device of claim 17, wherein the first set of layers comprises conductive traces, at least a portion of the conductive traces each electrically coupling a connector of the first coupling region to a connector of the second coupling region.

19. The electronic device of claim 18, wherein the second set of layers comprises a conductive material that provides an interference shield for electrical signals transmitted using the conductive traces.

20. The electronic device of claim 17, wherein the second set of layers is coupled to the first set of layers along a first portion of the flex circuit extending from the first coupling region and along a second portion of the flex circuit extending from the second coupling region.
